(19) United States
(12) Patent Application Publication
(10) Pub. No.: US 2025/0112058 A1
(43) Pub. Date: Apr. 3, 2025

(54) METHOD FOR DECAPSULATING PACKAGED INTEGRATED CIRCUIT

(71) Applicant: Tung Nguyen, San Diego, CA (US)

(72) Inventor: Tung Nguyen, San Diego, CA (US)

(21) Appl. No.: 18/480,135

(22) Filed: Oct. 3, 2023

(51) Int. Cl. H01L 21/56; H01L 21/66; H01L 21/67

(52) U.S. Cl. CPC H01L 21/565; H01L 21/67115; H01L 21/67126; H01L 22/12

(57) ABSTRACT

A method for decapsulating packaged integrated circuit is provided for the detection of counterfeit integrated circuit. The present invention pertains particularly to methods for application of heat for the decapsulation. The best way to ensure devices under test is not a counterfeit is to match the golden sample's die topography with that of the device under test. It is extremely difficult to replicate the unique topography and logo markings on the die. For an application like a failure analysis, it requires more expensive and involved steps to preserve the functionality of the die after the decapsulation. The decapsulation method for the detection of counterfeit only requires the preservation of markings of the die. The present invention provides for an efficient and economical decapsulation method for the detection of counterfeit utilizing new and novel techniques involving precise temperature control and related steps.

### BACKGROUND OF THE INVENTION

Packaged integrated circuits are present in most electronic devices. The packaged integrated circuit device is made of semiconductor die inside an individual package. Plastic encapsulation has been employed for years, typically utilizing epoxy or other plastic resin materials, which involves molding the protective material around the integrated circuit itself. Such integrated circuit devices are often sourced and manufactured elsewhere including counterfeit manufacturers.

It is clearly desirable to inspect the integrated circuit utilizing non-destructive testing procedures, which leave the entire encapsulated package structure intact. However, visual inspection, testing, failure analysis and repair of such encapsulated devices most often require physical access to the semiconductor die and other connection circuitry thereof. In such cases decapsulation of the package is necessary to allow for exposure of the circuit of interest from their outer covering.

Since the advent of integrated circuit plastic packaging, several techniques have been developed for removal of the protective material. One such technique, which is mechanical, is to grind the encapsulant back to a point to where the integrated circuit die and connections are exposed. Another technique is to use toxic chemicals etching away the packaging material. Plasma etching, while being very precise, is prohibitively expensive.

These methods do have disadvantages, however. For example, when using the mechanical grinding approach, it is difficult to know precisely when to stop the grinding, and physical damage to connections within the package is highly possible. Plasma etching is in many cases prohibitively expensive, and the fine control required can be a cause for a prohibitively lengthy process as well.

Chemical processes that can remove the encapsulant material are generally preferred in the art. Chemical etching provides a balance of precision and cost electiveness, and involves precise application of an acidic, heated corrosive substance. However, the process does also have certain disadvantages of toxicity if not handled properly in the adequate fume hood.

Aforementioned methods are meant for failure analysis. The process is lengthy and more involved for careful decapsulation to keep the part functional after the decapsulation. The lengthy and more involved process produces low volume output as the result.

The present invention is for counterfeit detection, not for failure analysis. Counterfeiting semiconductors has been a rapidly increasing trend, impacting a wide variety of electronics systems used by a wide gamut of involved parties—consumers, businesses, and military customers. The detection of counterfeit components has become an increasingly important priority for electronics manufacturers and component suppliers worldwide.

Technical measures to solve this problem include visual inspection of devices for marking errors on the package, electronic testing, or x-raying integrated circuit devices. The best way to ensure devices under test is not a counterfeit is to match the golden sample's die topography with that of the device under test. It is extremely difficult to replicate the die especially when there are logo and device type markings on the die. At this level of inspection, almost all counterfeiters would not have the resources to make a counterfeit die. The golden sample or exemplar is a device procured from an authorized distribution or directly from the original component manufacturer (OCM).

### SUMMARY OF THE INVENTION

In view of the foregoing background, the present invention offers a fast and efficient method and system for decapsulating a packaged integrated circuit, specifically designed for effective counterfeit detection. Frequent inspection using fast decapsulation method offers an effective solution for preventing counterfeiting.

The method includes steps of subjecting the encapsulant to heat to break the polymer bonds of the polymer resin to loosen the capsule. The loosened capsule can then be removed to expose the integrated circuit die within. The method further comprises a step of cleaning the integrated circuit die with deionized water. The water cleaned die is inspected under microscope for quality. The method may further comprise a step of cleaning the die with acid where traces of epoxy remain bonded to the surface of the die blocking the die marking(s).

Plastic packaging is utilized more extensively than any other type of packaging. Numerous tests were carried out on plastic packaging. Ceramics are used in some applications as encapsulating material. It requires higher energy processing as compared to plastics.

The present invention is a method for decapsulating integrated circuit in plastic packaging. The decapsulation method to keep the circuitry of the die functional after the decapsulation as in the failure analysis is more time consuming and resource intensive, compared to the decapsulation method without the post-decapsulation functionality requirement as in the counterfeit detection. The invention provides for an efficient and economical decapsulation method utilizing new and novel techniques involving precise temperature control and related steps. This method allows placing as many devices as a thermal chamber can accommodate, and completes the decapsulation task much faster producing high volume output.

### BRIEF DESCRIPTION OF DRAWINGS

FIG. 1 is a flow chart illustrating the process of decapsulating a packaged integrated circuit in accordance with the present invention.

FIG. 2 is an exemplary thermal chamber.

FIG. 3 is an exemplary cleaning device for ultrasonic bathing in 100% deionized water.

### DETAILED DESCRIPTION OF THE INVENTION

The present invention will now be described more fully hereinafter with reference to the accompanying drawings, in which a preferred embodiment of the invention is shown. This invention may, however, be embodied in many different forms and should not be construed as limited to the embodiment set forth herein. Rather, this embodiment is provided so that this disclosure will be thorough and complete, and will fully convey the scope of the invention to those skilled in the art.

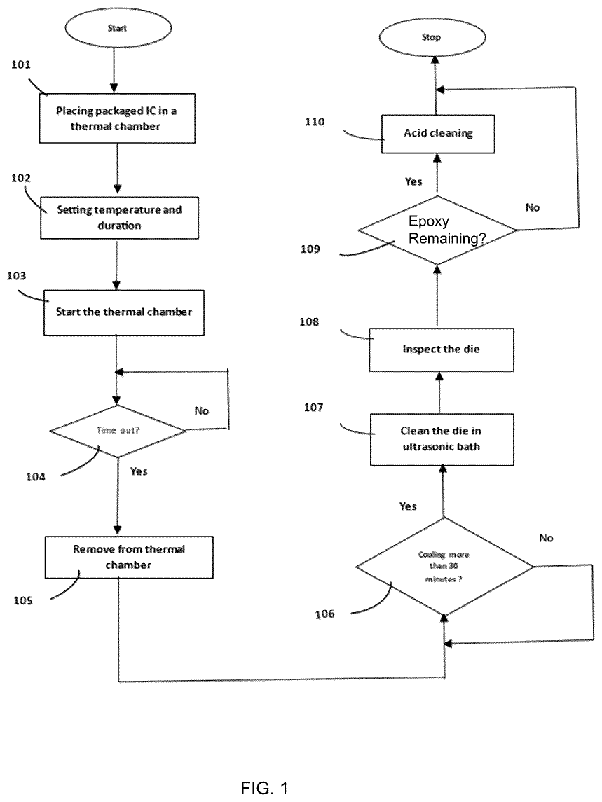

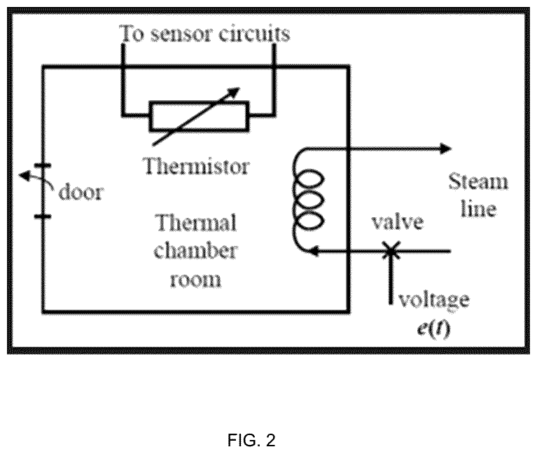

Referring to the block 101 of the FIG. 1 flow chart, the packaged integrated circuit is placed in a thermal chamber of FIG. 2. The packaged integrated circuit may include a lead frame carrying the external pins, an integrated circuit die, and bond wire extending between the lead frame and bond pads on the die, as would be readily appreciated by those skilled in the art.

In addition, the packaged integrated circuit includes an encapsulant surrounding the other components. The encapsulant is preferably a polymer resin-based epoxy. The encapsulant may be a thermosetting encapsulant including a polymer resin.

The thermal chamber of FIG. 2 comprises heating element, temperature control element, and time control element. The temperature control element is equipped with a temperature sensor and a logic circuit that turns on and off the heating element according to the sensed temperature of the thermal chamber. The time control element is equipped with a timer and a logic circuit that sends a cessation signal to the heating element once the timer reaches zero.

At the block 102 of FIG. 1, temperature, and time control of the thermal chamber of FIG. 2 are set.

At the block 103 of FIG. 1, the thermal chamber is activated subjecting the packaged integrated circuit to the radiation heat set at said temperature for said time duration.

Multiple tests were conducted with different combinations of temperature and time duration. In one embodiment, temperature range of 800° C. to 1000° C. with period of 5 to 10 minutes were tested. This combination resulted in damage to the die due to delaminated/cracked top surface layer of the die. Thus, it was determined to be inadequate for good die markings verification. In another embodiment, temperature range of 400° C. to 600° C. with period of 5 to 10 minutes were tested. This combination resulted in insufficient heating period to completely turn the epoxy that encapsulates the integrated circuit into ashes. Therefore, it made the removal of the die extremely difficult and potentially cracking the die during the process of removing remnant plastic pieces on the die using a tweezer. In still another embodiment, temperature range of 500° C. to 600° C. with period of 1.5 to 2 hours were tested. This test resulted in optimal range, turning the epoxy into ashes, decapsulating the integrated circuit. There were no plastic pieces remaining on the die requiring additional physical removal. The stated temperature and duration are accurate within 10%.

The embodiments are described in connection with the use of thermal chamber for applying a high temperature. However, it should be understood that other techniques and devices can also be used to provide heat treatment. Hereinafter, the term “heat treatment” means applying a high temperature state to a packaged integrated circuit.

Once the heating is completed as the time runs out, as shown by the block 104, the packaged integrated circuit is removed from the thermal chamber at the block 105, and allowed to cool to ambient temperature, i.e., normal room temperature, at least for 30 minutes, as shown by the block 106 of FIG. 1.

The 30-minute cooling duration is critical. Any time period shorter than the 30 minutes would result in thermal shock causing the die to crack. Cooling period of longer than 30 minutes does not affect the decapsulation. The epoxy has changed its property from solid plastic to ashes so that longer cooling period does not make the decapsulation any harder.

At the optimal range, most packages were turned into ashes. If not, the same process is repeated, two repeats at the maximum.

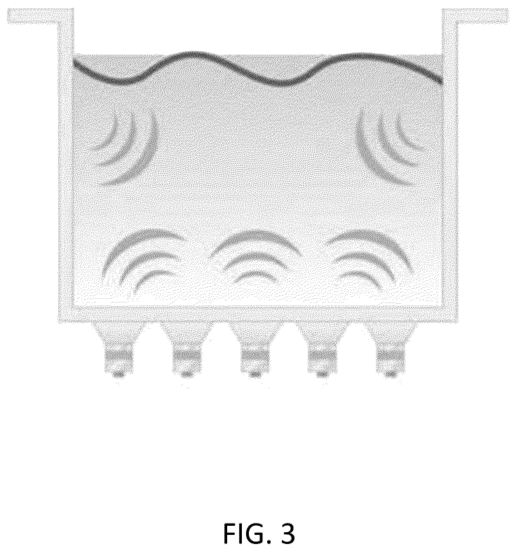

At the block 107 of FIG. 1, ultrasonic bathing in 100% deionized water gently removes loosened particles off the die. FIG. 3 is an exemplary ultrasonic bathing device.

The die is visually examined under a microscope for quality in the block 108 of FIG. 1.

In the block 110 of FIG. 1, optional cleaning using fuming nitric acid is performed to remove any remaining epoxy residue that may be adhered to the surface of the die, obstructing the die marking(s), as shown by the block 109 of FIG. 1.

Only 6 parts out of 1200 parts tested were needed to use fuming nitric acid to remove the remaining epoxy. That is, approximately 0.5% of the water cleaned dies required further cleaning with nitric acid.

The inventor was able to load as many devices as the thermal chamber could hold, and by doing so, completed the decapsulation task much quicker resulting in high volume output.

One skilled in the art, after being exposed to the teachings provided in the preceding descriptions and associated drawings, will likely conceive various modifications and alternative embodiments of the invention. Hence, it is important to note that the invention is not limited to the disclosed specific embodiments, and that modifications and alternative embodiments are intended to be encompassed within the scope of the appended claims.

Thus, the scope of the present disclosure is to be determined by the broadest permissible interpretation to the maximum extent allowed by law, of the following claims, and shall not be restricted or limited by the foregoing detailed description.

1. A method of decapsulating a packaged integrated circuit, comprising the steps of:
subjecting the packaged integrated circuit to radiation heat;
checking if further heat treatment is necessary;
cooling the heat-treated package to room temperature;
cleaning in 100% deionized water;
inspecting the water cleaned die; and
optional acid cleaning.

2. The step of subjecting the packaged integrated circuit to radiation heat of claim 1, wherein said packaged integrated circuit is placed into a thermal chamber.

3. The thermal chamber of claim 2, wherein the temperature of the thermal chamber is set in the range of 500° C. to 600° C.

4. The thermal chamber of claim 2, wherein the timer of the thermal chamber is set in the range of 1.5 to 2 hours.

5. The step of subjecting the packaged integrated circuit to radiation heat of claim 1, wherein said package is subjected to heat radiation at temperature set in claim 3 for the duration set in claim 4.

6. The step of checking if further heat treatment is necessary of claim 1, wherein a visual inspection is conducted to see if the plastic encapsulant is completely turned into ashes, and repeating the step of subjecting the packaged integrated circuit to radiation heat two repeats at the maximum if the plastic encapsulant is not completely turned into ashes.

7. The step of cooling of claim 1, wherein the heat treated packaged integrated circuit is taken out of the thermal chamber and left to cool down to room temperature for a duration of at least 30 minutes.

8. The cleaning in 100% deionized water step of claim 1, wherein the die is subject to cleaning in ultrasonic vibration bathing device filled with 100% deionized water.

9. The inspecting the water cleaned die step of claim 1, wherein visual inspection to see any epoxy residue adhered to the die is conducted under a microscope.

10. The optional acid cleaning step of claim 1, wherein fuming nitric acid is used to remove the epoxy residue bonded to the surface of the die blocking the die marking(s).
